(19) United States
(12) Patent Application Publication
(10) Pub. No.: US 2015/0287844 A1
(43) Pub. Date: Oct. 8, 2015

(54) SOLAR BATTERY MODULE AND SOLAR POWER GENERATION SYSTEM

(71) Applicant: SHARP KABUSHIKI KAISHA, Osaka-shi, Osaka (JP)

(72) Inventors: Yasushi Sainoh, Osaka-shi (JP); Yoshihisa Dotta, Osaka-shi (JP); Hiroyuki Ikawa, Osaka-shi (JP); Masatomo Tanahashi, Osaka-shi (JP); Shinji Nishioka, Osaka-shi (JP); Kohei Sawada, Osaka-shi (JP); Kentaro Usui, Osaka-shi (JP); Tomoo Imataki, Osaka-shi (JP); Hiroaki Itoh, Osaka-shi (JP)

(21) Appl. No.: 14/364,386

(22) PCT Filed: Dec. 10, 2012
(86) PCT No.: PCT/JP2012/081875

§ 371 Date: Jun. 11, 2014

(30) Foreign Application Priority Data
Dec. 12, 2011 (JP) 2011-271294
Dec. 12, 2011 (JP) 2011-271303

(51) Int. Cl. H01L 31/0216; H02S 40/30; H01L 31/068; H02S 30/10; H01L 31/0224; H01L 31/028

(52) U.S. Cl. CPC H01L 31/02167; H01L 31/022441; H01L 31/028; H01L 31/0682; H02S 30/10; H02S 40/30

(57) ABSTRACT

A solar battery module that can decrease the reduction in output is provided. The solar battery module (1) includes a solar battery panel (30) which includes: a solar battery cell (2) that includes an insulating passivation film (22) on a light reception surface; a translucent substrate (5) which is arranged on the side of the light reception surface of the solar battery cell; and a sealing member (4) which adheres the solar battery cell and the translucent substrate. A cell upper portion (4a) arranged on the light reception surface of the solar battery cell has an area resistivity of 1.36×10¹⁴ Ω·cm² or more.

### TECHNICAL FIELD

The present invention relates to a solar battery module and a solar power generation system, and more particularly relates to a solar battery module and a solar power generation system that include a solar battery cell having an insulating passivation film on a light reception surface.

### BACKGROUND ART

In recent years, a solar battery module has been developed that includes a so-called back surface electrode-type solar battery cell in which an n-electrode and a p-electrode are formed on the back surface side of a silicon substrate. For example, as shown in FIG. 12, a solar battery module 1001 that is a conventional example includes: a plurality of back surface electrode-type solar battery cells 1010 (hereinafter simply referred to as solar battery cells 1010); a connection member 1020 that connects the adjacent solar battery cells 1010; a sealing member 1021 that covers the solar battery cells 1010 and the connection member 1020; a translucent substrate 1022 and a back surface protective sheet 1023 that vertically sandwich the solar battery cells 1010, the connection member 1020 and the sealing member 1021; and a frame member 1024 (retaining member) that retains these components. As shown in FIG. 13, the solar battery cell 1010 includes: an n-type silicon substrate 1011 in which an n-type collector layer 1011a and a p-type collector layer 1011b are provided in the back surface side; a passivation film 1012 provided on the side of the upper surface (light reception surface) of the silicon substrate 1011; an n-electrode 1013 that is provided on the back surface side of the silicon substrate 1011 and that is electrically connected to the n-type collector layer 1011a; and a p-electrode 1014 that is electrically connected to the p-type collector layer 1011b. In FIG. 12, the n-electrode 1013 and the p-electrode 1014 are omitted.

When solar light is applied to the solar battery module 1001, a pair of an electron and a positive hole is produced within the silicon substrate 1011, and the electron and the positive hole are drawn to the n-type collector layer 1011a and the p-type collector layer 1011b, respectively. Thus, a predetermined output (power) is taken out. In the solar battery cell 1010, since no electrode is formed on the light reception surface side of the silicon substrate 1011, no shadow loss (the loss of light as a result of the electrode serving as a shadow) is produced.

A solar battery module in which a plurality of back surface electrode-type solar battery cells are connected is disclosed in, for example, patent document 1.

### RELATED ART DOCUMENT

### Patent Document

Patent document 1: JP-A-2010-16074

### DISCLOSURE OF THE INVENTION

### Problems to be Solved by the Invention

However, the inventors of the present application have found that when solar light is applied to the solar battery module 1001 described above to generate power, the output of the solar battery module 1001 may be disadvantageously reduced (the efficiency of power generation may be reduced). Specifically, the inventors of the present application have found the followings as a result of performing various examinations on the solar battery module 1001: in a solar battery module in which an electrode is provided on each of a light reception surface and a back surface used conventionally, a reduction in the output is unlikely to be produced; as the difference between the potential of a power generation circuit within the solar battery module 1001 and the potential of the frame member 1024 is increased, a reduction in the output is more likely to be produced; in a state where a water film is formed on the light reception surface of the solar battery module 1001 due to rainfall or the like, a reduction in the output is more likely to be produced.

Consequently, the inventors of the present application have estimated that the following mechanism causes the output of the solar battery module 1001 to be reduced.

Firstly, when the potential of the solar battery cell 1010 is higher than that of the surrounding (the frame member 1024 and the outside of the solar battery module 1001), the potential difference produces an electric field E on the light reception surface side of the solar battery cell 1010 in a direction shown in FIG. 14. Then, electrons included within the translucent substrate 1022 and the sealing member 1021 are collected on the side of the passivation film 1012 by the electric field E.

Secondary, a force is produced which collects positive holes on the light reception surface side of the silicon substrate 1011, that is, in the direction of the side where the passivation film 1012 is formed, such the positive holes are paired with the electrons collected on the light reception surface side of the passivation film 1012.

Thirdly, light is applied to the p-n joint of the solar battery cell 1010, and thus a pair of an electron and a positive hole is produced. Then, by the force that collects the positive holes described above, the produced positive holes are more likely to be moved in the direction of the passivation film 1012, and the proportion of the produced positive holes reaching the p-type collector layer 1011b provided on the back surface of the silicon substrate 1011 is reduced. When the silicon substrate 1011 is of n-type, since positive holes serving as carriers are low in number, the reduction in the proportion of the produced positive holes reaching the p-type collector layer 1011b means that the output current of the solar battery cell 1010 is reduced. In other words, the output of the solar battery module 1001 is rescued (the efficiency of power generation is reduced).

The present invention is made to solve the foregoing problem; an object of the present invention is to provide a solar battery module and a solar power generation system that can decrease the reduction in output without the configurations of a solar battery cell, the solar battery module and the solar power generation system being complicated.

### Means for Solving the Problem

To achieve the above object, according to the present invention, there is provided a solar battery module including a solar battery panel, where the solar battery panel includes: solar battery cell that includes an insulating passivation film on a light reception surface; a translucent substrate that is arranged on a side of the light reception surface of the solar battery cell; and a sealing member that is arranged between the solar battery cell and the translucent substrate, and a cell upper portion arranged on the light reception surface of the solar battery cell has an area resistivity of 1.36×10¹⁴ Ω·cm² or more.

In the present specification and the scope of claims, the translucent substrate refers to a substrate that is transparent to solar light (having a translucency).

In the solar battery module of the present invention, as described above, the cell upper portion arranged on the light reception surface of the solar battery cell has an area resistivity of 1.36×10¹⁴ Ω·cm² or more. Since on the cell upper portion arranged on the light reception surface of the solar battery cell, the sealing member and the translucent substrate are stacked and arranged, at least one of the sealing member and the translucent substrate on the cell upper portion has an area resistivity of 1.36×10¹⁴ Ω·cm² or more or the sum of the area resistivity of the sealing member and the area resistivity of the translucent substrate is preferably 1.36×10¹⁴ Ω·cm² or more. Although even when the sealing member and the translucent substrate are general insulating substances, a small number of free electrons are present in the substances, the area resistivity is increased, and thus the density of free electrons included in the sealing member and the translucent substrate on the cell upper portion is more reduced. Hence, even when a high potential difference is produced through the light reception surface of the solar battery cell, since a small number of free electrons are collected on the side of the passivation film in the sealing member and the translucent substrate, the density of the electrons collected on the side of the light reception surface (the side of the sealing member) of the passivation film is decreased. Since the force that collects positive holes on the side (the side of the silicon substrate) opposite to the side of the light reception surface of the passivation film is proportional to the density of the electrons collected on the side of the light reception surface (the side of the sealing member) of the passivation film, the density of the electrons collected on the side of the light reception surface (the side of the sealing member) of the passivation film is decreased, and thus it is possible to reduce the force that collects the positive holes generated in the silicon substrate in the side of the passivation film. Consequently, it is possible to decrease the reduction (the reduction in the efficiency of power generation) in the output of the solar battery module.

Preferably, in the solar battery module described above, the cell upper portion has an area resistivity of 1.36×10¹⁴ Ω·cm² or more at 85° C. When in a general insulating substance, a temperature is increased, the volume resistivity of the substance tends to be reduced. Hence, the insulating member (the sealing member and the translucent substrate) of the cell upper portion is configured to have an area resistivity of 1.36×10¹⁴ Ω·cm² or more even at 85° C., and thus it is possible to decrease the reduction in the output even if the solar battery module is used at a high temperature.

Preferably, in the solar battery module described above, the solar battery cell includes an n-type silicon substrate and an n-electrode and a p-electrode that are provided on a back surface of the silicon substrate. In general, since the potential of the solar battery cell is often higher than the potential of the surrounding (the retaining member retaining the translucent substrate and the outside of the solar battery module), when an n-type silicon substrate is used as a so-called back surface electrode-type solar battery cell where an n-electrode and a p-electrode are provided on the back surface, the output of the solar battery module is more likely to be reduced. Hence, the present invention is particularly effective when an n-type silicon substrate is used as the so-called back surface electrode-type solar battery cell.

Preferably, in the solar battery module described above, a conductive retaining member that retains an edge portion of the solar battery panel is further provided. Thus, it is possible to easily and inexpensively enhance the rigidity and the durability of the solar battery module.

Preferably, in the solar battery module described above, a forbidden band width of the passivation film is equal to or less than photon energy included in light passing through the sealing member and reaching the passivation film. Thus, since the passivation film can absorb the photon energy included in the light passing through the sealing member, it is possible to excite electrons in the passivation film into the state of free electrons and make them reach the silicon substrate. In other words, since the passivation film functions as a conductive member, and can pass the electrons collected on the side of the light reception surface of the passivation time from the interior of the sealing member to the silicon substrate, it is possible to reduce the accumulation of the electrons from the interior of the sealing member on the side of the light reception surface of the passivation film, with the result that it is possible to prevent the reduction in the output current of the solar battery cell.

Preferably, in the solar battery module in which the forbidden band width of the passivation film is equal to or less than photon energy, the forbidden band width of the passivation film is equal to or less than 3.5 eV. In this configuration, the passivation film can absorb the light of wavelengths more than about 350 nm. A typical sealing member for a solar battery module is configured to interrupt the light of wavelengths less than about 350 nm. Hence, as described above, the forbidden band width of the passivation film is made equal to or less than 3.5 eV, and thus the passivation film can absorb the light of wavelengths equal to or more than about 350 nm that passes through the sealing member.

Preferably, in the solar battery module in which the forbidden band width of the passivation film is equal to or less than photon energy, the forbidden band width of the passivation film is equal to or more than 3.1 eV. In this configuration, the light of wavelengths more than about 400 nm passes through without being absorbed by the passivation film. The relative spectral sensitivity characteristic of the solar battery cell using crystal silicon has almost no sensitivity to the light of wavelengths equal to or less than 400 nm, for example, as shown in FIG. 4 of JP-A-2002-231324. Hence, as described above, the forbidden band width of the passivation film is set at about 11 eV or more, and the passivation film is formed so as to transmit the light of wavelengths more than about 400 nm, and thus the light of wavelengths more than about 400 nm reaches the silicon substrate without being absorbed by the passivation film. In this way, it is possible to decrease the reduction in the efficiency of power generation of the solar battery cell caused by the passivation film.

Preferably, in the solar battery module in which the forbidden band width of the passivation film is equal to or less than photon energy, the passivation film includes a silicon compound film. In this configuration, it is possible to easily form the passivation film. Since the lattice constants of the silicon compound and the silicon substrate are close to each other, it is possible to reduce the production of a crystal defect in the interface between the silicon compound (the passivation film) and the silicon substrate, with the result that it is possible to enhance the quality of the passivation film.

Preferably, in the solar battery module in which the forbidden band width of the passivation film is equal to or less than photon energy, the passivation film includes an inorganic oxide film. In this configuration, it is possible to easily form the passivation film.

A solar power generation system of the present invention includes the solar battery module configured as described above. In this configuration, it is possible to obtain the solar power generation system that can decrease the reduction in output.

Preferably, in the solar power generation system described above, a conductive retaining member that retains an edge portion of the solar battery panel is provided, the retaining member is grounded and the potential of an output end through which power generated by the solar battery module is output is equal to or more than a ground potential. In general, when the retaining member is conductive, the retaining member is often grounded so that safety for an electric shock and the like is acquired. In the solar battery module installed as described above, when the potential of the solar battery cell that performs power generation within the solar battery module is equal to or more than the ground potential, the output of the solar battery module is more likely to be decreased. Hence, the present invention is particularly effective when the conductive retaining member retaining the edge portion of the solar battery panel is grounded, and the potential of the output end through which power generated by the solar battery module is output is equal to or more than the ground potential.

Preferably, in the solar power generation system described above, a plurality of solar battery modules are provided, the retaining member of all the solar battery modules is grounded and in at least one of the solar battery modules, the potential of the output end through which power generated by the solar battery module is output is equal to or more than the ground potential. Even in this configuration, it is possible to decrease the reduction in the output of the solar battery module in which the potential of the output end is equal to or more than the ground potential.

### Advantages of the Invention

As described above, in the present invention, it is possible to easily obtain the solar battery module and the solar power generation system that can decrease the reduction in output.

### BRIEF DESCRIPTION OF DRAWINGS

FIG. 1 A cross-sectional view showing the configuration of a solar battery module according to a first embodiment of the present invention;

FIG. 2 A cross-sectional view showing the configuration of a back surface electrode-type solar battery cell shown in FIG. 1 and according to the first embodiment of the present invention;

FIG. 3 A cross-sectional view for illustrating the movement of electrons and positive holes by an electric field generated in the solar battery module shown in FIG. 1 and according to the first embodiment of the present invention;

FIG. 4 A diagram showing a relationship of the time of power generation and output between examples 1 to 3 and comparative example 1;

FIG. 5 A cross-sectional view showing the configuration of a solar battery module according to a second embodiment of the present invention;

FIG. 6 A cross-sectional view for illustrating the movement of electrons and positive holes by an electric field generated in the solar battery module shown in FIG. 5 and according to the second embodiment of the present invention;

FIG. 7 A cross-sectional view showing the configuration of a solar battery module according to a variation of the present invention;

FIG. 8 A cross-sectional view showing the configuration of a solar battery module according to a third embodiment of the present invention;

FIG. 9 A cross-sectional view showing the configuration of a back surface electrode-type solar battery cell shown in FIG. 8 and according to the third embodiment of the present invention;

FIG. 10 An energy band diagram of a passivation film shown in FIG. 8 and according to the third embodiment of the present invention;

FIG. 11 A cross-sectional view for illustrating the movement of electrons and positive holes by an electric field generated in the solar battery module shown in FIG. 8 and according to the third embodiment of the present invention;

FIG. 12 A cross-sectional view showing the configuration of a solar battery module according to a conventional example;

FIG. 13 A cross-sectional view showing the configuration of a back surface electrode-type solar battery cell shown in FIG. 12 and according to the conventional example; and

FIG. 14 A cross-sectional view for illustrating the movement of electrons and positive holes by an electric field generated in the solar battery module shown in FIG. 12 and according to the conventional example.

### DESCRIPTION OF EMBODIMENTS

Embodiments of the present invention will be described below with reference to accompanying drawings. For ease of understanding, even a cross-sectional view may not be hatched.

### First Embodiment

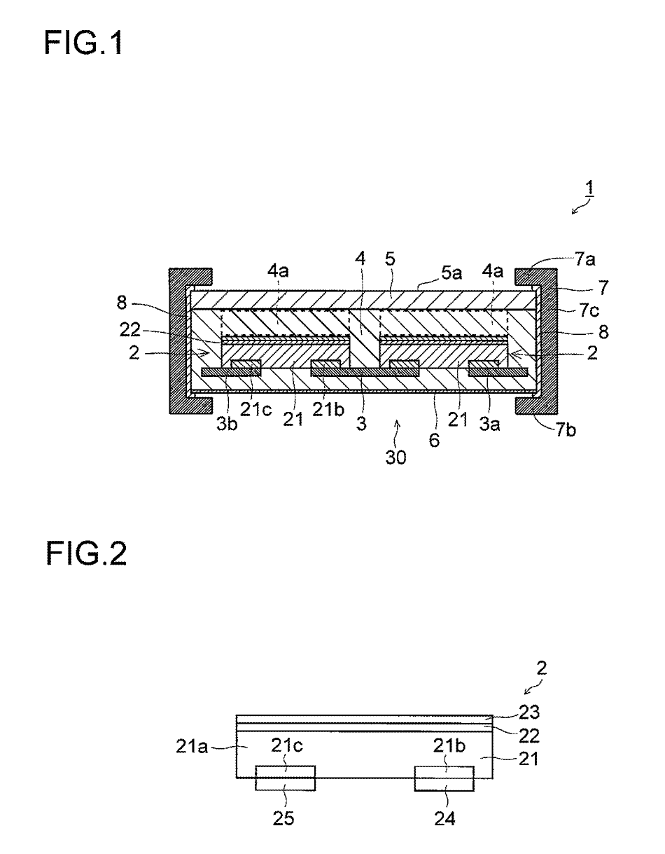

The structure of a solar battery module 1 according to a first embodiment of the present invention will first be described with reference to FIGS. 1 to 3. For simplification of the figures, solar battery cells are shown while their number is reduced.

As shown in FIG. 1, the solar battery module 1 according to the first embodiment of the present invention includes: a plurality of back surface electrode-type solar battery cells 2 (hereinafter simply referred to as solar battery cells 2); a connection member 3 that connects the solar battery cells 2 in series with each other; a sealing member 4 that covers the light reception surface side and the back surface side of the solar battery cells 2; a translucent substrate 5 and a back surface protective sheet 6 that vertically sandwich the solar battery cells 2 and the sealing member 4; and a frame member 7 (retaining member) that retains these components (solar battery panel 30). The solar battery panel 30 is formed with the solar battery cells 2, the connection member 3, the sealing member 4, the translucent substrate 5 and the back surface protective sheet 6. Although for simplification of the figure, in FIG. 1, only two solar battery cells 2 are shown, three or more solar battery cells 2 may be provided.

As shown in FIG. 2, the solar battery cell 2 includes: an n-type silicon substrate 21; an insulting passivation film 22 that is formed on the upper surface (light reception surface) of the silicon substrate 21 and that is formed with a silicon nitride film; an insulating antireflection film 23 that is formed on the passivation film 22 and that is formed with a silicon nitride film; and an n-electrode 24 and a p-electrode 25 that are provided on the back surface of the silicon substrate 21. In FIG. 1, the n-electrode 24 and the p-electrode 25 are omitted.

In the upper surface of the silicon substrate 21, an unillustrated texture structure (concave and convex structure) is formed. On the back surface of the silicon substrate 21, a passivation film (not shown) may also be formed. In this case, in the passivation film on the back surface, an opening portion for making the n-electrode 24 and the p-electrode 25 electrically continuous is preferably provided.

The silicon substrate 21 includes: an n-type region 21a; an n-type collector layer 21b that is provided on the back surface side of the silicon substrate 21 and that has an n-type impurity higher in concentration than the n-type region 21a; and a p-type collector layer 21c that is provided on the back surface side of the silicon substrate 21 and that has a p-type impurity. When solar light is applied to the solar battery cell 2, a pair of an electron and a positive hole is produced, and the electron is drawn to the n-type collector layer 21b and the positive hole is drawn to the p-type collector layer 21c.

The n-type collector layer 21b and the p-type collector layer 21c are ohmically in contact with the n-electrode 24 and the p-electrode 25, respectively. The n-electrode 24 and the p-electrode 25 of the adjacent solar battery cells 2 are electrically connected with the connection member 3 (see FIG. 1), and thus a plurality of solar battery cells 2 are connected in series. As shown in FIG. 1, the connection member 3 includes an output end 3a that is connected to the n-electrode 24 of the solar battery cell 2 arranged at one end (low potential side), and an output end 3b that is connected to the p-electrode 25 of the solar battery cell 2 arranged at the other end (high potential side). The output ends 3a and 3b described above are provided in order to output power generated by the solar battery module 1 (a plurality of solar battery cells 2).

The passivation film 22 preferably has a refractive index higher than the antireflection film 23. The passivation film 22 may be formed with, instead of a silicon nitride film, a silicon compound film such as a silicon oxide film or a silicon carbide film. The passivation film 22 may be formed with a dielectric film having a passivation effect of reducing the surface recombination of carriers (electrons and positive holes). The antireflection film 23 can be formed with, instead of a silicon nitride film, various oxide films such as a silicon oxide film and a titanium oxide film. The antireflection film 23 can be formed with another film having an antireflection effect together with the passivation film 22.

The sealing member 4 is arranged between the solar battery cell 2 and the translucent substrate 5, and adheres the solar battery cell 2 and the translucent substrate 5. The sealing member 4 is also arranged between the solar battery cell 2 and the back surface protective sheet 6, and adheres the solar battery cell 2 and the back surface protective sheet 6. In the present embodiment, the portion of the sealing member 4 arranged on the upper side of the solar battery cell 2 and the connection member 3 and the portion arranged on the lower side are formed of the same resin. Of the portion of the sealing member 4 arranged on the upper side of the solar battery cell 2 and the connection member 3, a cell upper portion 4a (portion enclosed by the broken lines of FIG. 1) arranged on the light reception surface of the solar battery cell 2 and the other portions are formed of the same resin. In other words, the portion of the sealing member 4 arranged on the upper side of the solar battery cell 2 and the connection member 3 is formed with one layer.

The sealing member 4 is formed with, for example, an insulating resin or the like that is transparent to solar light. The cell upper portion 4a of the sealing member 4 has an area resistivity of about 1.36×10¹⁴ Ω·cm² or more at a normal temperature (about 23° C.). When the cell upper portion 4a of the sealing member 4 has a thickness of, for example, about 0.04 cm or more, a material that has a volume resistivity of about 3.4×10¹⁵ Ω·cm or more at a normal temperature (about 23° C.) can be used as the sealing member 4. In general, when a temperature is increased, the volume resistivity of a resin tends to be decreased. On the other hand, ES C8990 specifies a suitability test on a ground-installed solar battery module that is suitable for a prolonged operation; in a test where a solar battery module is subjected to a high temperature, it is specified that 85° C. is set. Hence, the cell upper portion 4a of the sealing member 4 in the solar battery module 1 preferably has an area resistivity of about 1.36×10¹⁴ Ω·cm² or more even at 85° C. Since the sealing member 4 is often brought into an appropriately cured state by thermal processing or the like, and often deforms very little by the temperature, if it is assumed that the thickness of the sealing member 4 is not varied by the temperature, a material that has a volume resistivity of about 3.4×10¹⁵ Ω·cm or more can be used as the sealing member 4 even at 85° C. Thus, even if the solar battery module that can be subjected to a general outdoor weather for a long period of time is brought into a high temperature state, it is possible to decrease the reduction in output.

As the sealing member 4, for example, a silicon resin (such as OE-6336 made by Dow Corning Corp.) can be used. It is also possible to use a resin that is obtained by adjusting the formula and composition of a widely used ethylene vinyl acetate resin to increase its volume resistivity or a resin, such as an olefin-based resin, whose volume resistivity is high. A cross-linking promoter and an ultraviolet absorber may be added to the resin of the sealing member 4.

Although the translucent substrate 5 is formed with, for example, a glass substrate or a PC (polycarbonate resin) that is transparent to solar light, the translucent substrate 5 is not particularly limited as long as it is transparent to solar light.

As the back surface protective sheet 6, for example, a sheet material or the like can be used that is formed with a conventionally used weather-resistant film. As the sheet material formed with a weather-resistant film, for example, an insulating film such as a PET (polyethylene terephthalate) film can be used. Instead of the back surface protective sheet 6, for example, a glass substrate may be used.

The frame member 7 retains the entire perimeter of the edge portion of the solar battery panel 30 through an insulating end surface sealing member 8. The end surface sealing member 8 has a water-stop function and elasticity, and is arranged between the end surface (the end surface (outer perimeter surface) of the translucent substrate 5, the sealing member 4 and the back surface protective sheet 6) of the solar battery panel 30 and the frame member 7.

The frame member 7 is formed of, for example, a metal such as aluminum and is conductive. The frame member 7 is formed in the shape of, for example, a rectangle in which a window portion is formed in the center portion, as seen in plan view. As shown in FIG. 1, the frame member 7 has a cross section in the shape of the letter U.

The frame member 7 includes a locking portion 7a that locks the upper surface 5a of the translucent substrate 5, a back surface locking portion 7b that locks the back surface of the back surface protective sheet 6 and a side wall portion 7c that connects the locking portion 7a and the back surface locking portion 7b.

In the solar power generation system including the solar battery module 1 described above, the frame member 7 is grounded through unillustrated wiring so that safety for an electric shock and the like is acquired. Although the potential of the output end 3a and the output end 3b is determined by the state of a load connected, in the present embodiment, even if the potential of the output end 3a and the output end 3b is higher than a ground potential, it is possible to decrease the reduction (the reduction in the efficiency of power generation) in the output of the solar battery module 1.

The solar power generation system may include a plurality of solar battery modules 1. In this case, in all the solar battery modules 1, the potential of the output end 3a and the output end 3b may be equal to or more than the ground potential or in one (at least one) of the solar battery modules 1, the potential of the output end 3b may be higher than the ground potential.

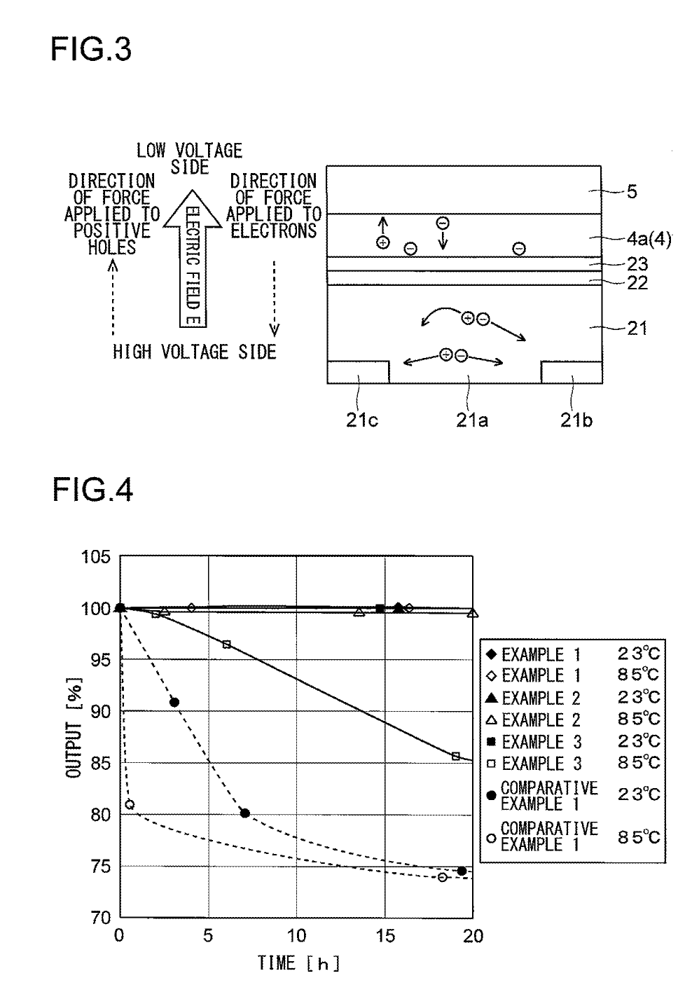

Since in the solar battery module 1 of the present embodiment, the cell upper portion 4a of the sealing member 4 has an area resistivity of about 1.36×10¹⁴ Ω·cm² or more, the density of free electrons per unit area in the cell upper portion 4a of the sealing member 4 is lowered. Hence, even when as shown in FIG. 3, a high potential difference is produced through the light reception surface of the solar battery cell 2, since a small number of free electrons are collected on the side of the passivation film 22 in the sealing member 4, the density of the electrons collected on the side of the light reception surface (the side of the sealing member 4) of the passivation film 22 is decreased. Since the force that collects positive holes on the side (the side of the silicon substrate 21) opposite to the side of the light reception surface of the passivation film 22 is proportional to the density of the electrons collected on the side of the light reception surface (the side of the sealing member 4) of the passivation film 22, the density of the electrons collected on the side of the light reception surface (the side of the sealing member 4) of the passivation film 22 is decreased, and thus it is possible to reduce the movement of the positive holes generated in the silicon substrate 21 to the side of the passivation film 22. In this way, it is possible to decrease the reduction (the reduction in the efficiency of power generation) in the output of the solar battery module 1.

Even if a small number of free electrons are collected on the side of the passivation film 22 in the daytime (in the power generation), since the collected free electrons are diffused at night (in the non-power generation), free electrons are prevented from being unilaterally accumulated on the side of the passivation film 22. Hence, it is possible to maintain the output of the solar battery module 1 for a long period of time (for example, 10 years or more).

When as described above, the potential of the solar battery cell 2 is higher than that of the surrounding (the frame member 7 and the outside of the solar battery module 1), and the n-type silicon substrate 21 is used as the back surface electrode-type solar battery cell 2, the output of the solar battery module 1 is easily reduced. Hence, the present invention is particularly effective when the n-type silicon substrate 21 is used. Likewise, when the potential of the solar battery cell 2 is lower than that of the surrounding (the frame member 7 and the outside of the solar battery module 1), and the p-type silicon substrate 21 is used as the back surface electrode-type solar battery cell 2, the output of the solar battery module 1 is easily reduced. Even in this case, the cell upper portion 4a of the sealing member 4 arranged on the light reception surface of the solar battery cell 2 has an area resistivity of about 1.36×10¹⁴ Ω·cm² or more, and thus it is possible to decrease the reduction in the output of the solar battery module 1.

As described above, the cell upper portion 4a preferably has an area resistivity of about 1.36×10¹⁴ Ω·cm² or more at 85° C. In general, when a temperature is increased, the insulation (area resistivity) of the material (the sealing member 4) tends to be reduced. On the other hand, in the suitability test on a ground-installed solar battery module that is specified by HS C8990 and that is suitable for a prolonged operation, it is expected that the temperature of the solar battery module is increased up to 85° C. Hence, as described above, the cell upper portion 4a is configured so as to have an area resistivity of about 1.36×10¹⁴ Ω·cm² or more even at 85° C., and thus it is possible to decrease the reduction in the output even when the temperature is increased up to the expected temperature in the operation of the solar battery module 1.

As described above, the cell upper portion 4a (the sealing member 4) can be made to have an area resistivity of about 1.36×10¹⁴ Ω·cm² or more by combining, as necessary, a volume resistivity unique to the sealing member 4 and the thickness of the cell upper portion 4a of the sealing member 4. For example, since the silicon resin OE-6336 made by Dow Corning Corp. has a volume resistivity of 4×10¹⁶ Ω·cm, this resin is arranged on the cell upper portion such that the thickness of the resin is 0.5 mm, with the result that the area resistivity of the cell upper portion 4a of the sealing member 4 can be set at 2×10¹⁵ Ω·cm².

It is also possible to use an olefin resin having a high volume resistivity such as the polyethylene disclosed in JP-A-9-17235.

As described above, when the frame member 7 is grounded, and the potential of the output ends 3a and 3b through which power generated by the solar battery module 1 is output is equal to or more than the ground potential, the output of the solar battery module 1 is easily reduced. Hence, the present invention is particularly effective when the potential of the output ends 3a and 3b in the solar battery module 1 is equal to or more than the ground potential.

This also holds true for a case where when the solar power generation system has a plurality of solar battery modules 1, the potential of the output ends 3a and 3b in at least one of the solar battery modules 1 is equal to or more than the ground potential.

A confirmatory experiment that was performed to confirm the effects of the solar battery module 1 will then be described with reference to FIG. 4 and table 1. In the confirmatory experiment, examples 1 to 3 corresponding to the present embodiment and comparative example 1 were used to check variations in output with the time of power generation.

In example 1, an olefin resin that has a volume resistivity of about 7.3×10¹⁶ Ω·cm at 23° C. and a volume resistivity of about 3.4×10¹⁵ Ω·cm at 85° C. was used to form the sealing member 4. The thickness of the cell upper portion 4a of the sealing member 4 was set at about 0.4 mm. Thus, the cell upper portion 4a of the sealing member 4 had an area resistivity of about 2.92×10¹⁵ Ω·cm² at 23° C. and an area resistivity of about 1.36×10¹⁴ Ω·cm² at 85° C. The other structures of example 1 were the same as those of the solar battery module 1 described above.

In example 2, an olefin resin that has a volume resistivity of about 1.3×10¹⁷ Ω·cm at 23° C. and a volume resistivity of about 3.4×10¹⁵ Ω·cm at 85° C. was used to form the sealing member 4. The thickness of the cell upper portion 4a of the sealing member 4 was set at about 0.4 mm. Thus, the cell upper portion 4a of the sealing member 4 had an area resistivity of about 5.2×10¹⁵ Ω·cm² at 23° C. and an area resistivity of about 1.36×10¹⁴ Ω·cm² at 85° C. The other structures of example 2 were the same as those of example 1.

In example 3, an olefin resin that has a volume resistivity of about 1.5×10¹⁷ Ω·cm at 23° C. and a volume resistivity of about 3.2×10¹⁴ Ω·cm at 85° C. was used to form the sealing member 4. The thickness of the cell upper portion 4a of the sealing member 4 was set at about 0.4 mm. Thus, the cell upper portion 4a of the sealing member 4 had an area resistivity of about 6×10¹⁵ Ω·cm² at 23° C. and an area resistivity of about 1.28×10¹³ Ω·cm² at 85° C. The other structures of example 3 were the same as those of example 1.

In comparative example 1, an ethylene vinyl acetate resin that has a volume resistivity of about 2.4×10¹⁴ Ω·cm at 23° C. and a volume resistivity of about 1.2×10¹² Ω·cm at 85° C. was used to form a sealing member. The thickness of the cell upper portion of the sealing member was set at about 0.4 mm. Thus, the cell upper portion of the sealing member had an area resistivity of about 9.6×10¹² Ω·cm² at 23° C. and an area resistivity of about 4.8×10¹⁰ Ω·cm² at 85° C. The other structures of comparative example 1 were the same as those of example 1.

In examples 1 to 3 and comparative example 1, the output (generation power) with the time of power generation was measured. Specifically, with respect to the light reception surface (the upper surface 5a of the translucent substrate 5) of the solar battery module, a voltage of +600 V was applied to the solar battery cell, and an output after a predetermined time had elapsed since the start of the power generation was measured. The experiment was performed for each of a case where an ambient temperature was about 23° C. and a case where the ambient temperature was about 85° C. Then, with the assumption that an output immediately after the start of the power generation (after a zero time elapsed) was 1, standardization was performed. The output immediately after the start of the power generation (after a zero time elapsed) was measured without the application of a voltage of +600 V. The results are shown in FIG. 4.

As shown in FIG. 4, in examples 1 and 2, it was found that the output was little reduced as the time elapsed. In example 3, in the case where the ambient temperature was about 23° C., it was found that the output was little reduced as the time elapsed whereas in the case where the ambient temperature was about 85° C., it was found that the output was reduced as the time elapsed. In comparative example 1, it was found that the output was reduced as the time elapsed.

Specifically, in examples 1 and 2, both in the case where the ambient temperature was about 23° C. and in the case where the ambient temperature was about 85° C., the output was reduced by 0.5% or less after about 20 hours had elapsed.

In example 3, in the case where the ambient temperature was about 23° C., the output was not reduced after about 20 hours had elapsed. On the other hand, in the case where the ambient temperature was about 85° C., the output was reduced by about 14.2% after about 20 hours had elapsed.

In comparative example 1, in the case where the ambient temperature was about 23° C., the output was reduced by about 25.3% after about 20 hours had elapsed. In the case where the ambient temperature was about 85° C., the output was reduced by about 25.9% after about 20 hours had elapsed. In comparative example 1, even in the case where the ambient temperature was about 23° C., the output was reduced by about 19.7% after about 7 hours had elapsed.

When the output was determined to be reduced if the output was reduced by 5% or more after about 20 hours had elapsed, and the output was determined not to be reduced when the output was reduced by 5% or less after about 20 hours had elapsed, in examples 1 and 2, the output was not reduced. In example 3, the output was not reduced in the case where the ambient temperature was about 23° C. whereas the output was reduced in the case of about 85° C. In comparative example 1, the output was reduced.

Whether or not the output was reduced after about 20 hours had elapsed in the experiment described above is shown in table 1.

TABLE 1

| | | Volume | | | |
|---|---|---|---|---|---|
| Sealing | Temperature | resistivity | Cell upper portion | Area resistivity | |
| member | [° C.] | [Ω · cm] | thickness [mm] | [Ω · cm²] | Output decrease |
| Example 1 | 23 | About 7.3 × 10¹⁶ | 0.4 | About 2.92 × 10¹⁵ | ∘ (no decrease) |
| | 85 | About 3.4 × 10¹⁵ | 0.4 | About 1.36 × 10¹⁴ | ∘ |
| Example 2 | 23 | About 1.3 × 10¹⁷ | 0.4 | About 5.2 × 10¹⁵ | ∘ |
| | 85 | About 3.4 × 10¹⁵ | 0.4 | About 1.36 × 10¹⁴ | ∘ |
| Example 3 | 23 | About 1.5 × 10¹⁷ | 0.4 | About 6.0 × 10¹⁵ | ∘ |
| | 85 | About 3.2 × 10¹⁴ | 0.4 | About 1.28 × 10¹³ | x (decrease) |
| Comparative | 23 | About 2.4 × 10¹⁴ | 0.4 | About 9.6 × 10¹² | x |
| Example 4 | 85 | About 1.2 × 10¹² | 0.4 | About 4.8 × 10¹⁰ | x |

It is found that as shown in table 1, when the cell upper portion of the sealing member has an area resistivity of about 1.36×10¹⁴ Ω·cm² or more, it is possible to decrease the reduction in the output of the solar battery module.

### Second Embodiment

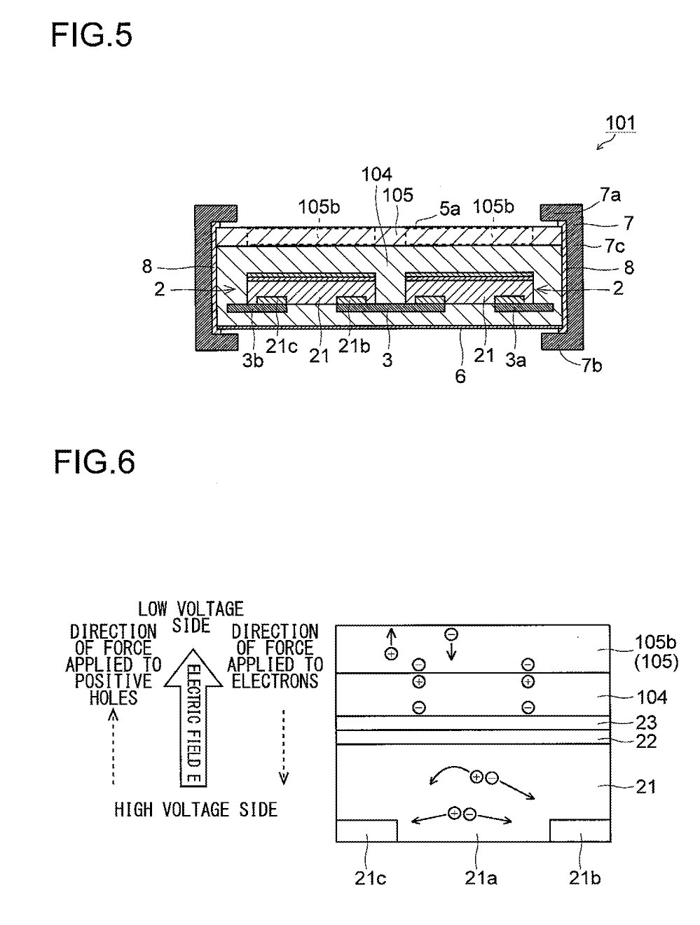

In a solar battery module 101 of a second embodiment, as shown in FIG. 5, a sealing member 104 is formed of, for example, an ethylene vinyl acetate resin.

Of a translucent substrate 105, a cell upper portion 105b (portion enclosed by the broken lines of FIG. 5) arranged on the light reception surface of the solar battery cell 2 has an area resistivity of about 1.36×10¹⁴ Ω·cm² or more at a normal temperature (about 23° C.). When the cell upper portion 105b of the translucent substrate 105 has the same thickness of about 3.2 mm as a typical solar battery module, the translucent substrate 105 preferably has a volume resistivity of about 4.25×10¹⁴ Ω·cm or more at a normal temperature (about 23° C.). The cell upper portion 105b of the translucent substrate 105 preferably has an area resistivity of about 1.36×10¹⁴ Ω·cm² or more at 85° C., and the translucent substrate 105 preferably has a volume resistivity of about 4.25×10¹⁴ Ω·cm or more at 85° C.

As the translucent substrate 105, for example, a glass, a polycarbonate resin or the like is used, and thus the translucent substrate 105 can have an area resistivity of 1.36×10¹⁴ Ω·cm² or more at 85° C. As an example of the glass, an alkali-free glass such as NA35 made by HOYA Corporation can be used. As an example of the polycarbonate resin, Panlite made by Teijin Chemicals Ltd. can be used. It is also possible to increase the area resistivity by providing a multi-layer structure with the translucent substrate 105. For example, between two general glass plates, a translucent insulating member such as PET may be sandwiched. In this structure, it is possible not only to increase the area resistivity of the translucent substrate 105 with only an inexpensive material but also to reduce, by adopting a laminated glass structure, when the glass plate is broken, the scattering of the broken pieces of the glass.

In the solar battery module 101 of the present embodiment, since the translucent substrate 105 has an area resistivity of about 1.36×10¹⁴ Ω·cm² or more, the density of free electrons per unit area in the cell upper portion 105b of the translucent substrate 105 is decreased. Hence, as shown in FIG. 6, even if a high potential difference is produced through the light reception surface of the solar battery cell 2, the density of free electrons collected on the side of the passivation film 22 (the side of the sealing member 104) in the translucent substrate 105 is decreased. Since the sealing member 104 and the translucent substrate 105 are electrically connected in series, the density of electrons moving in the sealing member 104 is equal to the density of electrons moving in the translucent substrate 105. Hence, the density of electrons moving in the translucent substrate 105 is reduced, and thus as in the first embodiment, the density of electrons collected on the side of the light reception surface of the passivation film 22 (the side of the sealing member 104) is reduced, with the result that it is possible to reduce the movement of the positive holes generated in the silicon substrate 21 to the side of the passivation film 22. In this way, it is possible to decrease the reduction (the reduction in the efficiency of power generation) in the output of the solar battery module 101.

The other structures in the second embodiment are the same as in the first embodiment.

The present invention can be described as follows, including the first and second embodiments discussed above. Specifically, the area resistivity of the cell upper portion is sufficiently higher than that of the passivation film 22, most of the potential difference applied from the outside of the module through the light reception surface of the solar battery cell is absorbed by the resistance of the cell upper portion and thus the voltage applied to the passivation film 22 is reduced, with the result that an inversion layer is prevented from being produced in the interface between the passivation film 22 and the silicon substrate 21. For example, when the interface with the passivation film 22 of the silicon substrate 21 is n-type, a predetermined voltage (turnover voltage) or more is applied to the passivation film 22 such that the side of the silicon substrate 21 has a higher voltage, a p-type inversion layer can be formed on the surface of the silicon substrate 21. Hence, preferably, the potential difference with the silicon substrate 21 applied from the outside of the module is divided by the area resistivity of the cell upper portion and the area resistivity of the passivation film 22, with the result that the voltage applied to the passivation film 22 is set lower than the turnover voltage described above. Although the embodiment described above discusses the result of the examination that has been performed using the predetermined cell and the application voltage condition, even if the configuration of the passivation film 22 of the cell is changed to vary the area resistivity of the cell upper portion or the turnover voltage or even if the external application voltage is varied, it is possible to decrease the reduction (the reduction in the efficiency of power generation) in the output of the solar battery module 1 by satisfying the above relationship.

It should be considered that the first and second embodiments and the examples are illustrative and not restrictive in all respects. The scope of the present invention is indicated not by the description of the first and second embodiments and the examples but by the scope of claims, and furthermore, meanings equivalent to the scope of claims and all modifications within the scope are included.

For example, although in the first and second embodiments, the example where the n-type silicon substrate is used has been described, the present invention is not limited to this configuration, and a p-type silicon substrate may be used.

Although in the first and second embodiments, the case where the solar battery cell is the back surface electrode type has been described, the present invention is not limited to this configuration. Since even when the solar battery cell where the electrode is provided in each of the light reception surface and the back surface is used, the output of the solar battery module may be reduced, it is effective that the present invention is applied to a solar battery module using the solar battery cell where the electrode is provided in each of the light reception surface and the back surface.

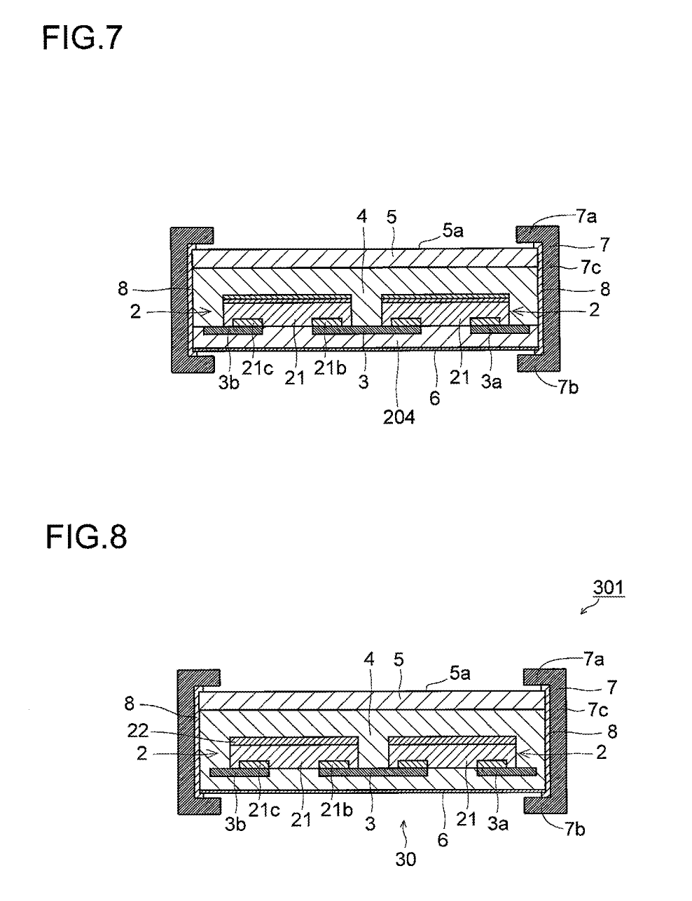

Although in the first and second embodiments, the example where, of the sealing member, the portion arranged on the upper side of the solar battery cell and the connection member and the portion arranged on the lower side are formed of the same resin has been described, the present invention is not limited to this configuration. For example, as in a solar battery module according to a variation of the present invention shown in FIG. 7, the sealing member 4 arranged on the upper side of the solar battery cell 2 and the connection member 3 and a sealing member 204 arranged on the lower side of the solar battery cell 2 and the connection member 3 may be formed of different resins. In this case, the sealing member 204 arranged on the lower side of the solar battery cell 2 and the connection member 3 may not be transparent to solar light, and may not have an area resistivity of about 1.36×10¹⁴ Ω·cm² or more. This type of configuration is particularly effective for a case where the sealing member 4 is expensive.

Although in the first and second embodiments, the example where the cell upper portion of the sealing member and the other portions are formed of the same resin has been described, the present invention is not limited to this example, and the cell upper portion of the sealing member and the other portions may be formed of different resins. In this case, the portions other than the cell upper portion of the sealing member may not have an area resistivity of about 1.36×10¹⁴ Ω·cm² or more.

The intensity of an electric field generated around the light reception surface of the solar battery cell arranged on the side where the potential difference with the outside of the module is large is higher than that of an electric field generated around the light reception surface of the solar battery cell arranged on the side where the potential difference with the outside of the module is small. Hence, when, for example, 10 solar battery cells are connected in series, only the sealing member that seals, for example, 5 solar battery cells arranged on the side where the potential difference with the outside of the module is large may be formed to have an area resistivity of about 1.36×10¹⁴ Ω·cm² or more.

Although in the first and second embodiments, the example where the frame member (retaining member) is conductive has been described, the retaining member may be formed with, for example, an insulting member. With this configuration, it is possible to decrease the increase in the intensity of the electric field generated around the light reception surface of the solar battery cell, and thus it is possible to more decrease the reduction in the output of the solar battery module. The retaining member may be formed with a conductive member (metal) and an insulating member.

Although in the first and second embodiments, the example where the sealing member is adhered to the solar battery cell and the translucent substrate has been described, the present invention is not limited to this example, and the sealing member may simply be in contact with the solar battery cell and the translucent substrate. As long as the sealing member is arranged between the solar battery cell and the translucent substrate, it may not be in contact with the solar battery cell and the translucent substrate.

Although in the first and second embodiments, the example where the antireflection film is provided on the passivation film has been described, the present invention is not limited to this example, and the antireflection film may be omitted.

### Third Embodiment

The structure of a solar battery module 301 according to a third embodiment of the present invention will be described with reference to FIGS. 8 to 11. For simplification of the figures, solar battery cells are shown while their number is reduced.

As shown in FIG. 8, the solar battery module 301 according to the third embodiment of the present invention includes: a plurality of back surface electrode-type solar battery cells 2 (hereinafter simply referred to as solar battery cells 2); a connection member 3 that connects the solar battery cells 2 in series with each other; a sealing member 4 that covers the light reception surface side and the back surface side of the solar battery cells 2; a translucent substrate 5 and a back surface protective sheet 6 that vertically sandwich the solar battery cells 2 and the sealing member 4; and a frame member 7 (retaining member) that retains these components (solar battery panel 30). The solar battery panel 30 is formed with the solar battery cells 2, the connection member 3, the sealing member 4, the translucent substrate 5 and the back surface protective sheet 6. Although for simplification of the figure, in FIG. 8, only two solar battery cells 2 are shown, three or more solar battery cells 2 may be provided.

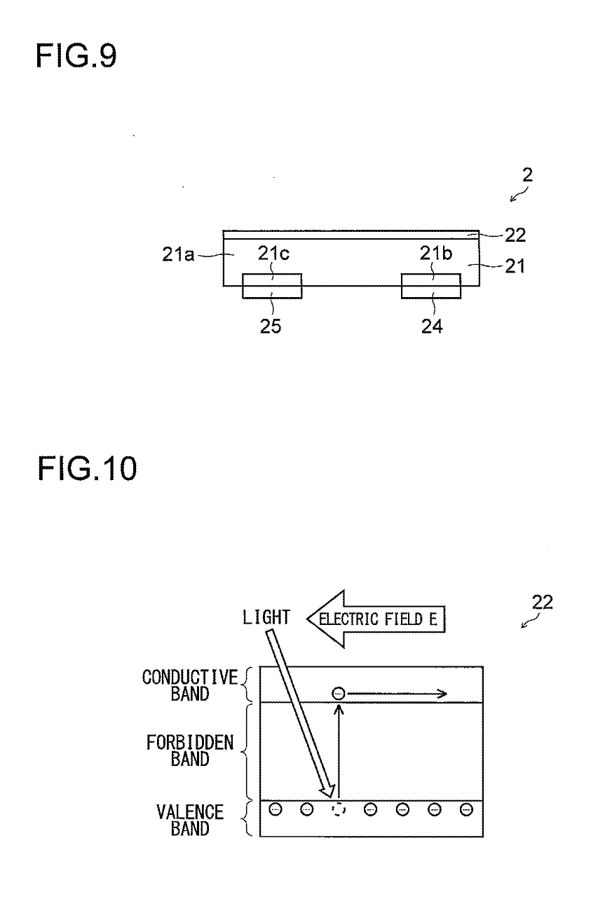

As shown in FIG. 9, the solar battery cell 2 includes: an n-type silicon substrate 21; an insulting passivation film 22 that is formed on the upper surface (light reception surface) of the silicon substrate 21; and an n-electrode 24 and a p-electrode 25 provided on the back surface of the silicon substrate 21. In FIG. 8, the n-electrode 24 and the p-electrode 25 are omitted. In the present embodiment, the insulating passivation film 22 is directly formed on the side of the light reception surface of the silicon substrate 21. In other words, the passivation film 22 and the silicon substrate 21 are in contact with each other.

In the upper surface of the silicon substrate 21, an unillustrated texture structure (concave and convex structure) is formed. On the back surface of the silicon substrate 21, a passivation film (not shown) may also be provided. In this case, in the passivation film on the back surface, an opening portion for making the n-electrode 24 and the p-electrode 25 electrically continuous is preferably provided.

The silicon substrate 21 includes: an n-type region 21a; an n-type collector layer 21b that is provided on the back surface side of the silicon substrate 21 and that has an n-type impurity higher in concentration than the n-type region 21a; and a p-type collector layer 21c that is provided on the back surface side of the silicon substrate 21 and that has a p-type impurity. When solar light is applied to the solar battery cell 2, a pair of an electron and a positive hole is produced, and the electron is drawn to the n-type collector layer 21b and the positive hole is drawn to the p-type collector layer 21c.

The n-type collector layer 21b and the p-type collector layer 21c are ohmically in contact with the n-electrode 24 and the p-electrode 25, respectively. The n-electrode 24 and the p-electrode 25 of the adjacent solar battery cells 2 are electrically connected with the connection member 3 (see FIG. 8), and thus a plurality of solar battery cells 2 are connected in series. As shown in FIG. 8, the connection member 3 includes an output end 3a that is connected to the n-electrode 24 of the solar battery cell 2 arranged at one end (low potential side), and an output end 3b that is connected to the p-electrode 25 of the solar battery cell 2 arranged at the other end (high potential side). The output ends 3a and 3b described above are provided in order to output power generated by the solar battery module 301 (a plurality of solar battery cells 2).

The silicon substrate 21 is formed of crystal silicon. Hence, for example, as shown in FIG. 4 of JP-A-2002-231324, the solar battery cell 2 is sensitive to the light of wavelengths equal to or more than about 400 nm but equal to or less than about 1100 nm, and is little sensitive to the light of the wavelengths equal to or less than about 400 nm.

The passivation film 22 has a forbidden band width equal to or less than photon energy included in light passing through the sealing member 4 and reaching the passivation film 22. In other words, the sealing member 4 is formed so as to transmit light including photon energy more than the forbidden band width of the passivation film 22. Preferably, the forbidden band width of the passivation film 22 is, for example, equal to or more than about 3.1 eV but equal to or less than about 3.5 eV. The forbidden band width of the passivation film 22 is set at, for example, about 3.5 eV or less, and thus the passivation film 22 can absorb the light of wavelengths equal to or more than about 350 nm that passes through the sealing member 4. Moreover, the forbidden band width of the passivation film 22 is set at, for example, about 3.1 eV or more, and thus the passivation film 22 can transmit the light of wavelengths equal to or more than about 400 nm (can make the light reach the silicon substrate 21).

As the passivation film 22 described above, a SiC film (having a forbidden band width of about 3.26 eV), a TiO₂ film (having a forbidden band width of about 3.5 eV) or the like can be used. It is also possible to use a conventionally used silicon nitride film whose forbidden band width is controlled to be equal to or more than about 3.1 eV but equal to or less than about 3.5 eV such as by the adjustment of a nitrogen composition ratio. Specifically, it is possible to use, as the passivation film 22 of the present invention, an insulating member in which a so-called internal photoelectric effect where electrons are excited by photons to allow the electrons to be moved to the silicon substrate 21 is caused by the light of wavelengths equal to or more than about 350 nm. Furthermore, the passivation film 22 more preferably does not absorb the light of wavelengths equal to or more than about 400 nm. The SIC film and the silicon nitride film whose forbidden band width is controlled to be equal to or more than about 3.1 eV but equal to or less than about 3.5 eV is one example of a “silicon compound film” according to the present invention. The TiO₂ film is an example of an “inorganic oxide film” according to the present invention.

The sealing member 4 is arranged between the solar battery cell 2 and the translucent substrate 5, and adheres the solar battery cell 2 and the translucent substrate 5. The sealing member 4 is also arranged between the solar battery cell 2 and the back surface protective sheet 6, and adheres the solar battery cell 2 and the back surface protective sheet 6. The sealing member 4 is formed of, for example, an insulating resin that is transparent to solar light. The sealing member 4 can be formed of, for example, an ethylene vinyl acetate resin or another resin.

In general, an ultraviolet absorber is often added to the resin of the sealing member 4 in the solar battery module so that degradation such as yellowing or decomposition is prevented from being caused by change of the quality through ultraviolet light. Hence, the sealing member 4 has the property of interrupting the light of wavelengths less than about 350 nm. In other words, the sealing member 4 has the property of transmitting not only the light of wavelengths equal to or more than about 400 nm but equal to or less than about 1100 nm but also the light of wavelengths that can be absorbed by the passivation film 22 of the present invention (for example, near-ultraviolet light of wavelengths equal to or more than about 350 nm but equal to or less than about 400 nm). The sealing member 4 on the light reception surface side of the solar battery cell 2 and the sealing member 4 on the back surface side thereof may be formed of a different resin. In this case, the sealing member 4 on the back surface side of the solar battery cell 2 may differ in spectral transmission characteristic from the sealing member 4 on the light reception surface side of the solar battery cell 2.

The translucent substrate 5 is formed with, for example, a glass substrate or a PC (polycarbonate resin) that is transparent to solar light. The material of the translucent substrate 5 is not particularly limited; as in a general translucent substrate, the translucent substrate 5 transmits not only the light of wavelengths equal to or more than about 400 nm but equal to or less than about 1100 nm but also the light of wavelengths that can be absorbed by the passivation film 22 of the present invention (for example, near-ultraviolet light of wavelengths equal to or more than about 350 nm but equal to or less than about 400 nm).

As the back surface protective sheet 6, for example, a sheet material or the like can be used that is formed with, for example, a conventionally used weather-resistant film. As the sheet material formed with a weather-resistant film, for example, an insulating film such as a PET (polyethylene terephthalate) film can be used. Instead of the back surface protective sheet 6, for example, a glass substrate may be used.

The frame member 7 retains the entire perimeter of the edge portion of the solar battery panel 30 through an insulating end surface sealing member 8. The end surface sealing member 8 has a water-stop function and elasticity, and is arranged between the end surface (the end surface (outer perimeter surface) of the translucent substrate 5, the sealing member 4 and the back surface protective sheet 6) of the solar battery panel 30 and the frame member 7.

The frame member 7 is formed of, for example, a metal such as aluminum and is conductive. The frame member 7 is formed of, for example, aluminum, and thus it is possible not only to enhance its durability but also to reduce its weight. The frame member 7 is formed in the shape of a rectangle in which a window portion is formed in the center portion as seen in plan view. As shown in FIG. 8, the frame member 7 has a cross section in the shape of the letter U.

The frame member 7 includes: an upper surface retaining portion 7a that is arranged above the upper surface 5a of the translucent substrate 5 which is the light reception surface of the solar battery panel 30 and that retains the upper surface of the solar battery panel 30; a back surface retaining portion 7b that is arranged below the back surface of the back surface protective sheet 6 and that retains the lower surface of the solar battery panel 30; a side wall portion 7c that connects the upper surface retaining portion 7a and the back surface retaining portion 7b.

In the solar power generation system including the solar battery module 301 described above, the frame member 7 is grounded through unillustrated wiring so that safety for an electric shock and the like is acquired. Although the potential of the output end 3a and the output end 3b is determined by the state of a load connected, in the present embodiment, it is expected that the potential of the output end 3a and the output end 3b is higher than the ground potential.

The solar power generation system may include a plurality of solar battery modules 301. In this case, in all the solar battery modules 301, the potential of the output end 3a and the output end 3b may be equal to or more than the ground potential or in one (at least one) of the solar battery modules 301, the potential of the output end 3b may be higher than the ground potential.

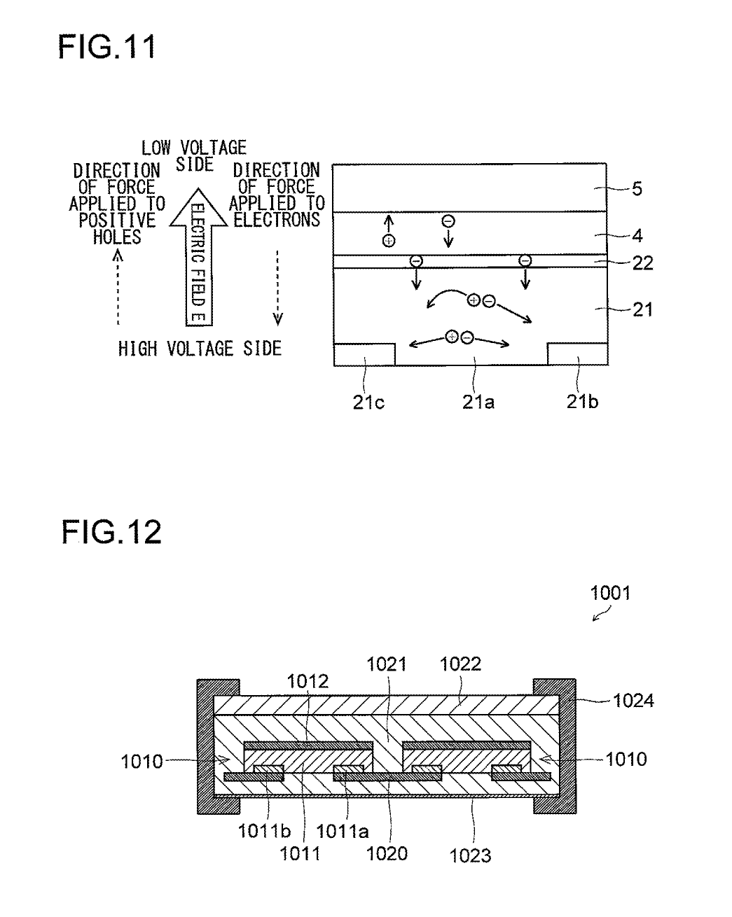

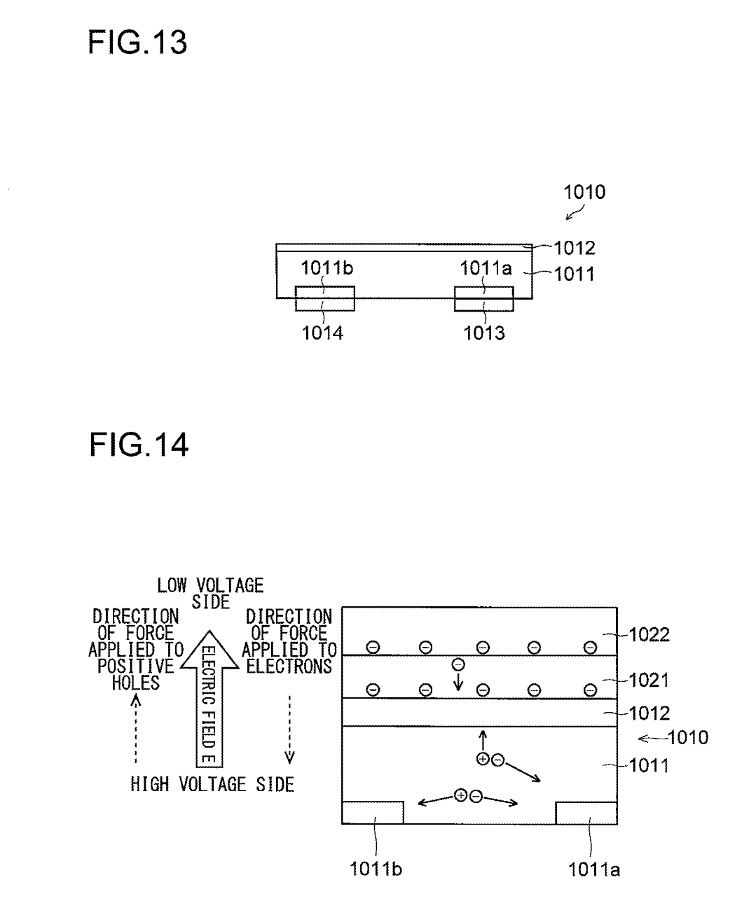

In the solar battery module 301 of the present embodiment, the forbidden band width of the passivation film 22 is set at, for example, about 3.5 eV or less, and thus the passivation film 22 can absorb the light of wavelengths equal to or more than about 350 nm that passes through the sealing member 4. Thus, as shown in FIG. 10, in the passivation film 22, an electron that is normally prevented from being moved because a valence band is filled with electrons passes through the forbidden band and is excited to a conductive band, in the valence band, a positive hole is generated so as to be paired with the excited electron and the electron and the positive hole can be moved along an electric field. In other words, the passivation film 22 behaves so as to be electrically conductive as a result of the internal photoelectric effect caused by the absorption of light by the passivation film 22. In this way, as shown in FIG. 11, when an electric field is generated around the light reception surface of the solar battery cell 2, though electrons in the sealing member 4 attempt to be collected in the vicinity of the interface portion with the passivation film 22, the electrons practically can pass through the passivation film 22 to reach the silicon substrate 21. Thus, it is possible to reduce the accumulation of electrons in the vicinity of the interface portion between the passivation film 22 and the sealing member 4. Since the density (charge density) of electrons in the vicinity of the interface portion between the passivation film 22 and the sealing member 4 is reduced, and thus the electric field applied to the vicinity of the interface portion between the passivation film 22 and the silicon substrate 21 is decreased, the force for making the generated positive holes travel in the direction of the passivation film 22 is decreased and the generated positive holes more easily reach the p-type collector layer 21c, with the result that it is possible to decrease the reduction in the output current that can be taken out of the solar battery cell 2.

In a conventional passivation film, a silicon oxide film (having a forbidden band width of about 9 eV) or a silicon nitride film (having a forbidden band width of about 5 to 6 eV) is often used. The silicon oxide film having a forbidden band width of about 9 eV can absorb only the light of wavelengths equal to or less than about 140 nm; the silicon nitride film having a forbidden band width of about 5 to 6 eV can absorb only the light of wavelengths equal to or less than about 210 nm to about 250 nm. Since the light of wavelengths equal to or more than about 250 nm is interrupted by a general sealing material (or the atmosphere) as described above, the light does not reach the passivation film. Hence, in a conventional solar battery module, it is impossible to excite the electrons of the passivation film.

The other structures in the third embodiment are the same as in the first and second embodiments.

In the present embodiment, as described above, the forbidden band width of the passivation film 22 is equal to or less than a photon energy included in the light that passes through the sealing member 4 and that reaches the passivation film 22. Thus, the passivation film 22 can absorb the photon energy included in the light transmitted by the sealing member 4. That the passivation film 22 can absorb the photon energy means that electrons, with which the valence band is filled and which are normally prevented from being moved are excited by the conductive band. As the electrons are excited, positive holes are generated in the valence band. In this way, the electrons that are moved into the conductive band and the positive holes that are generated in the valence band can be moved as carriers along the electric field. In other words, although the passivation film 22 is an insulating member, the electrons can pass through the passivation film 22 as if the passivation film 22 were conductive by the carriers generated in the passivation film 22. Hence, the electrons collected from the interior of the sealing member 4 on the side of the light reception surface of the passivation film 22 can be passed through to the silicon substrate 21 without being accumulated in the vicinity of the interface portion with the passivation film 22. Thus, the potential (electric field) applied between the side of the light reception surface of the passivation film 22 (the side of the sealing member 4) and the side of the silicon substrate 21 is decreased, with the result that it is possible to reduce the movement of the positive holes generated in the silicon substrate 21 to the side of the passivation film 22. Thus, it is possible to decrease the reduction (the reduction in the efficiency of power generation) in the output of the solar battery module 301.

On the light reception surface of the passivation film 22, an electrode and a conductive layer may be provided. If the quality or the thickness of the passivation film 22 is not uniform within a cell surface or if the spectral transmission characteristic of the sealing member 4 is not uniform within the surface, the conductivity caused by the internal photoelectric effect of the passivation film 22 may not be uniform within the solar battery cell surface. An electrode and a conductive layer are provided on the light reception surface of the passivation film 22, and thus the movement of the electrons in the light reception surface of the passivation film 22 is enhanced. Hence, even if a region where the conductive effect of the passivation film 22 is low is produced, electrons are moved to a region where the conductive effect of the passivation film 22 is high, and thus it is possible to prevent electrons from being accumulated over the entire region of the solar battery cell surface, with the result that it is possible to decrease the reduction (the reduction in the efficiency of power generation) in the output of the solar battery module 301. As the conductive layer described above, for example, a film or the like that becomes conductive by mixing the metal minute particles of silver or the like with the silicon nitride film or the like can be used. In this case, the thickness and the quality of the film are controlled, and thus it is also possible to make the film have an antireflection function. When as described above, an electrode and a conductive layer are provided on the light reception surface side of the solar battery cell 2, though a small loss of the light entering the silicon substrate 21 of the solar battery cell 2 is inevitably made, since it is possible to reliably prevent electrons from being accumulated over the entire region of the solar battery cell surface, it is possible to more reliably prevent the reduction in the output of the solar battery cell 2.

As described above, the forbidden band width of the passivation film 22 is about 3.5 eV or less. Thus, the passivation film 22 can absorb light of wavelengths equal to or more than about 350 nm. The ultraviolet absorber is added to the sealing member 4, and thus the sealing member 4 is configured so as to interrupt the light of wavelengths less than about 350 nm. Hence, as described above, the forbidden band width of the passivation film 22 is set at about 3.5 eV or less, and thus the passivation film 22 can absorb the light of wavelengths equal to or more than about 350 nm that is transmitted by the sealing member 4.

As described above, the forbidden band width of the passivation film 22 is about 3.1 eV or more. Thus, the passivation film 22 can transmit the light of wavelengths more than about 400 nm. The relative spectral sensitivity characteristic of the solar battery cell 2 using crystal silicon has almost no sensitivity to the light of wavelengths equal to or less than 400 nm. Hence, as described above, the forbidden band width of the passivation film 22 is set at about 3.1 eV or more, and the passivation film 22 is formed so as to transmit the light of wavelengths more than about 400 nm, and thus the light of wavelengths more than about 400 nm reaches the silicon substrate 21 without being absorbed by the passivation film 22. In this way, it is possible to decrease the reduction in the efficiency of power generation of the solar battery cell 2 caused by the passivation film 22.

As described above, the passivation film 22 is formed with, for example, a SIC film having a forbidden band width of about 3.26 eV, and of the light transmitted by the sealing member 4, the light of wavelengths equal to or more than about 350 nm but equal to or less than about 380 nm can be absorbed by the passivation film 22. The passivation film 22 is formed with a silicon compound such as a SiC film, and the silicon substrate 21 is doped with an additive, and thus it is possible to easily form the passivation film 22 formed with a silicon compound. Since the lattice constants of a silicon compound and the silicon substrate 21 are close to each other, it is possible to reduce the production of a crystal defect in the interface between the silicon compound (the passivation film 22) and the silicon substrate 21, with the result that it is possible to enhance the quality of the passivation film.

As described above, the passivation film 22 is formed with, for example, a TiO₂ film having a forbidden band width of about 3.5 eV, and of the light transmitted by the sealing member 4, the light of wavelengths equal to or more than about 350 nm but equal to or less than about 354 nm can be absorbed by the passivation film 22.

When as described above, the potential of the solar battery cell 2 is higher than that of the surrounding (the frame member 7 and the outside of the solar battery module 301), and the n-type silicon substrate 21 is used as the back surface electrode-type solar battery cell 2, the output of the solar battery module 301 is easily reduced. Hence, the present invention is particularly effective for the solar power generation system of such a combination. Likewise, when the potential of the solar battery cell 2 is lower than that of the surrounding (the frame member 7 and the outside of the solar battery module 301), and the p-type silicon substrate is used as the back surface electrode-type solar battery cell 2, since the output of the solar battery module 301 is easily reduced, the present invention is effective.

The frame member 7 in the solar power generation system is often grounded due to safety or the like whereas the potential of the output ends 3a and 3b through which power generated by the solar battery module 301 is output is often determined by the specifications, the operation conditions and the like of a load (such a power conditioner) connected. Hence, it is often difficult to arbitrarily set the relationship between the potential of the solar battery cell 2 in the solar power generation system and the potential of the surrounding (the frame member 7 and the outside of the solar battery module 301). In the present embodiment, even if the above potential relationship is formed in which the output of the solar battery module 301 is easily reduced, it is possible to decrease the reduction in the output of the solar battery module 301.

This also holds true for a case where when the solar power generation system has a plurality of solar battery modules 301, the potential of the output ends 3a and 3b in at least one of the solar battery modules 301 is equal to or more than the ground potential. Since even in such a configuration, the output of the solar battery module where the potential of the output ends is equal to or more than the ground potential is likely to be lowered, the present embodiment is applied to at least the corresponding solar battery module, and thus it is possible to decrease the reduction in the output of the solar battery module.

It should be considered that the third embodiment is illustrative and not restrictive in all respects. The scope of the present invention is indicated not by the description of the third embodiment but by the scope of claims, and furthermore, meanings equivalent to the scope of claims and all modifications within the scope are included.

For example, although in the third embodiment, the example where the n-type silicon substrate is used has been described, the present invention is not limited to this configuration, and a p-type silicon substrate may be used. In this case, when the frame member 7 is grounded, and the potential of the output ends 3a and 3b through which power generated by the solar battery module 301 is output is equal to or less than the ground potential, the output of the solar battery module 301 is easily reduced. Hence, the present invention is particularly effective when the potential of the output ends 3a and 3b in the solar battery module 301 is equal to or less than the ground potential.

Although in the third embodiment, the case where the solar battery cell is the back surface electrode type has been described, the present invention is not limited to this configuration. Since even when the solar battery cell where the electrode is provided in each of the light reception surface and the back surface is used, the output of the solar battery module may be reduced, it is also effective that the present invention is applied to a solar battery module using the solar battery cell where the electrode is provided in each of the light reception surface and the back surface.

Although in the third embodiment, the example where the forbidden band width of the passivation film is set at 3.1 eV or more but 3.5 eV or less has been described, the present invention is not limited to this configuration. As long as the forbidden band width of the passivation film is equal to or less than the photon energy included in the light passing through the sealing member and reaching the passivation film, the forbidden band width may be more than 3.5 eV. For example, when the sealing member transmits the light of wavelengths less than about 350 nm, the forbidden band width of the passivation film may be more than 3.5 eV. When if the passivation film absorbs part of the light of wavelengths more than about 400 nm, the output of the solar battery module is little reduced, the forbidden band width of the passivation film may be less than 3.1 eV.

Although in the third embodiment, the example where the frame member (retaining member) is conductive has been described, the retaining member may be formed with, for example, an insulting member. In this configuration, since it is possible to decrease the increase in the intensity of an electric field applied to the light reception surface of the solar battery cell, it is possible to more decrease the reduction in the output of the solar battery module. The retaining member may be formed with a conductive member (metal) and an insulting member.

An antireflection film may be provided on the passivation film. In this case, the antireflection film may be so as to be lower in thickness than the passivation film. The antireflection film can also be formed with a silicon nitride film, various oxide films such as a silicon oxide film or a titanium oxide film. The antireflection film can also be formed with another film having an antireflection effect together with the passivation film.

An electrode and a conductive layer may be provided on the passivation film. In this configuration, even if the quality or the thickness of the passivation film is not uniform within a cell surface or ever if the spectral transmission characteristic of the sealing member is not uniform within the surface, since it is possible to reliably reduce the accumulation of electrons over the entire region of the solar battery cell, it is possible to more reliably prevent the reduction in the output of the solar battery cell. In this case, the antireflection film may be used as the conductive layer when the antireflection film is provided on the passivation film.

Configurations obtained by combining, as necessary, the configurations of the embodiments, the examples and the variations described above are also included in the technical scope of the present invention.

### LIST OF REFERENCE SYMBOLS

1, 101, 301 solar battery module
2 back surface electrode-type solar battery cell (solar battery cell)
3a, 3b output end
4, 104 sealing member
4a cell upper portion
5, 105 translucent substrate
105b cell upper portion
7 frame member (retaining member)
21 silicon substrate
22 passivation film
24 n-electrode
25 p-electrode
30 solar battery panel

1-15. (canceled)

16. A solar battery module comprising a solar battery panel,
wherein the solar battery panel includes:
a solar battery cell that includes an insulating passivation film on a light reception surface;
a translucent substrate that is arranged on a side of the light reception surface of the solar battery cell;
a first sealing member that is arranged between the solar battery cell and the translucent substrate; and
a second sealing member that is arranged on a side opposite to the side of the light reception surface of the solar battery cell,
the first sealing member has an area resistivity of 1.36×10¹⁴ Ω·cm² or more and
the second sealing member has an area resistivity less than 1.36×10¹⁴ Ω·cm².

17. The solar battery module of claim 16,
wherein the first sealing has an area resistivity of 1.36×10¹⁴ Ω·cm² or more at 85° C.

18. The solar battery module of claim 17,
wherein the first sealing has an area resistivity of 2.92×10¹⁵ Ω·cm² or more at 23° C.

19. The solar battery module of claim 16,
wherein the first sealing has an area resistivity of 1.36×10¹⁴ Ω·cm² or more but 6×10¹⁵ Ω·cm² or less in a region of 23° C. or more but 85° C. or less.

20. The solar battery module of claim 16,
wherein the translucent substrate has an area resistivity of 1.36×10¹⁴ Ω·cm² or more.

21. The solar battery module of claim 16,
wherein the solar battery cell includes an n-type silicon substrate and an n-electrode and a p-electrode that are provided on a back surface of the silicon substrate.

22. The solar battery module of claim 16, further comprising:
a conductive retaining member that retains an edge portion of the solar battery panel.

23. The solar battery module of claim 16,
wherein a forbidden band width of the passivation film is equal to or less than photon energy included in light passing through the sealing member and reaching the passivation film.

24. The solar battery module of claim 23,
wherein the forbidden band width of the passivation film is equal to or less than 3.5 eV.

25. A solar power generation system comprising:
the solar battery module of claim 16.

26. The solar power generation system of claim 25, further comprising:
a conductive retaining member that retains an edge portion of the solar battery panel,
wherein the retaining member is grounded, and
a potential of an output end through which power generated by the solar battery module is output is equal to or more than a ground potential.

27. The solar power generation system of claim 25, comprising:
a plurality of the solar battery modules,
wherein the retaining member of all the solar battery modules is grounded, and
in at least one of the solar battery modules, a potential of an output end through which power generated by the solar battery module is output is equal to or more than a ground potential.
